(19) United States
(12) Patent Application Publication
(10) Pub. No.: US 2022/0312622 A1
(43) Pub. Date: Sep. 29, 2022

(54) SERVER CHASSIS DESIGN FOR HIGH POWER DENSITY ELECTRONICS THERMAL MANAGEMENT

(71) Applicant: Baidu USA LLC, Sunnyvale, CA (US)

(72) Inventor: TIANYI GAO, San Jose, CA (US)

(21) Appl. No.: 17/212,130

(22) Filed: Mar. 25, 2021

(51) Int. Cl. H05K 7/14; H05K 7/20

(52) U.S. Cl. CPC H05K 7/1489; H05K 7/20736

(57) ABSTRACT

Embodiments disclose a server chassis of an electronic rack. The server chassis includes a tray to contain one or more information technology (IT) components. The server chassis is stackable in a stack on an electronic rack, and where each server chassis is divisible into a top section and the bottom section in one design. The bottom section of the server includes the tray. The top section of the server chassis includes: a secured panel, the secured panel being secured to the server chassis, one or more frames adjustably attached to the secured panel, and one or more cooling units attachable to the one or more frames. The one or more cooling units to interface with the one or more IT components to cool the one or more IT components, where the one or more frames are relocatable to a different position on the secured panel.

### FIELD OF THE INVENTION

Embodiments of the present invention relate generally to server and data center cooling. More particularly, embodiments of the invention relate to a server chassis design for high power density electronics thermal management.

### BACKGROUND

Generally, computing motherboard includes various interfaces to exchange data with various components. Such interfaces include a peripheral component interconnect (PCI), which accepts a peripheral printed circuit board (PCB). The peripheral PCB (or peripheral device) is generally smaller than the motherboard and may include electronic devices such as, e.g., graphics processing units (GPU), cryptographic accelerators, application specific integrated circuits (ASIC), high computing based IC chips or chiplets, and so forth. Various standards may be used with a peripheral component interconnect, such as, PCI, PCI-X, AGP, PCIe (PCI express), etc. The commonality of these standards is that they all enable intercommunication between components mounted on the motherboard and components mounted on the peripheral PCB, with different speeds.

With the increase in modern computational requirements, more and more tasks are offloaded from the main CPU to other components, including components mounted on the peripheral PCB. Consequently, the processing power of the peripheral PCB increases, which increase the demand for energy, thus increasing heat dissipation.

With the more diverse workload and the computing architecture becoming more heterogenous, a new thermal management solution is needed that is interoperable with different server system design and peripheral PCB configurations.

### BRIEF DESCRIPTION OF THE DRAWINGS

Embodiments of the invention are illustrated by way of example and not limitation in the figures of the accompanying drawings in which like references indicate similar elements.

FIG. 1 is a perspective view of a server chassis according to one embodiment.

FIG. 2A is a top view of a top cooling section of a server chassis according to one embodiment.

FIG. 2B is a front view of a top cooling section illustrating a frame having a single mounting arm according to one embodiment.

FIG. 3A is a top view of a top cooling section of a server chassis according to one embodiment.

FIG. 3B is a front view of a top cooling section illustrating a frame having double mounting arms according to one embodiment.

FIG. 4A is a side view of a top cooling section illustrating a locking kit in an unlocked position according to one embodiment.

FIG. 4B is a side view of a top cooling section illustrating a locking kit in a locked position according to one embodiment.

FIG. 5 is a front view of a frame illustrating an example locking kit according to one embodiment.

FIG. 6 is a front view of a top cooling section illustrating a locked and an unlocked locking kits according to one embodiment.

FIG. 7A is a front view of a chassis assembled with one or more cooling units according to one embodiment.

FIG. 7B is a side view of a chassis assembled with one or more cooling units according to one embodiment.

FIG. 8A is a front view of a chassis assembled with one or more cooling units according to one embodiment.

FIG. 8B is a top view of a chassis assembled with one or more cooling units according to one embodiment.

FIG. 9A is a front view of a chassis assembled with one or more cooling units support a first peripheral devices arrangement according to one embodiment.

FIG. 9B is a front view of a chassis assembled with one or more cooling units support a second peripheral devices arrangement according to one embodiment.

FIG. 10 illustrates that a cooling unit is insertable from the top of the chassis according to one embodiment.

FIG. 11A is a front view of a chassis illustrating cooling units and peripheral devices are insertable and/or removable from a front/back of a chassis according to one embodiment.

FIG. 11B is a side view of a chassis illustrating cooling units and peripheral devices are insertable and/or removable from a front/back of a chassis according to one embodiment.

FIG. 12A is a front view of a chassis illustrating spacings when a peripheral PCB is interfaced with a main board according to one embodiment.

FIG. 12B is a front view of a chassis illustrating spacings when a peripheral PCB is not interfaced to a main board according to one embodiment.

FIG. 13 is a front view of a rack according to one embodiment.

FIG. 14 is a perspective view of a server rack with systems of different power densities and peripheral configurations according to one embodiment.

FIG. 15 is a block diagram illustrating an example of an electronic rack according to one embodiment.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

Embodiments of the present disclosure provide a server chassis layout compatible with server systems having different power density and/or peripheral device configurations, in an electronic rack used in a data center. The server chassis is hot-swappable and cooling units used in the server chassis can be serviced and/or replaced without having to remove the server chassis from the electronic rack. The cooling units can support air cooling or liquid/fluid cooling. Note that server systems with different energy density can refer to servers running a different number of peripheral devices. Different peripheral device configurations can refer to peripheral devices with different form factors and/or interfaced at different peripheral expansion locations on a main board.

According to one embodiment, a server chassis of an electronic rack includes: a tray to contain one or more information technology (IT) components. The server chassis is stackable in a stack on an electronic rack, and where each server chassis is divisible into a top section and the bottom section, where the bottom section includes the tray. The top section of the server chassis includes: a secured panel, the secured panel being secured to the server chassis, one or more frames adjustably attached to the secured panel, and one or more cooling units attachable to the one or more frames. The one or more cooling units to interface with the one or more IT components to cool the one or more IT components, where the one or more frames are relocatable to a different position on the secured panel.

In one embodiment, a frame includes a mountable arm and the one or more cooling units are mountable on the mounting arm. In one embodiment, the one or more IT components include one or more peripheral component interconnect express (PCIE) devices, and the one or more frames are relocatable to a different position on the secured panel while a server having the one or more IT components is in operation.

In one embodiment, the secured panel includes one or more recessed channels, wherein a first portion of a frame is insertable into a recessed channel of the one or more recessed channels. In one embodiment, the server chassis further includes a locking kit insertable between a first portion of a frame and the secured panel, the locking kit is turnable to lock the frame to the secured panel.

In one embodiment, a locking kit includes an elliptical-shaped pin and a first end of a frame includes an elliptical-shaped opening, wherein the elliptical-shaped pin is insertable into the elliptical-shaped opening. In one embodiment, the secured panel includes one or more first cushion layers and one or more second cushion layers facing the one or more first cushion layers, wherein the one or more first cushion layers and the one or more second cushion layers form one or more recessed channels.

In one embodiment, if a locking kit is in a locked position, the lock kit causes a top portion of a frame to press against a second cushion layer, which in turn, causes a PCIE device coupled to the frame to interface with a PCIE slot. In one embodiment, if a locking kit is in an unlocked position, a PCIE device associated with the locking kit is elevated from a PCIE slot. In one embodiment, the cooling unit includes a radiator and a cooling fan.

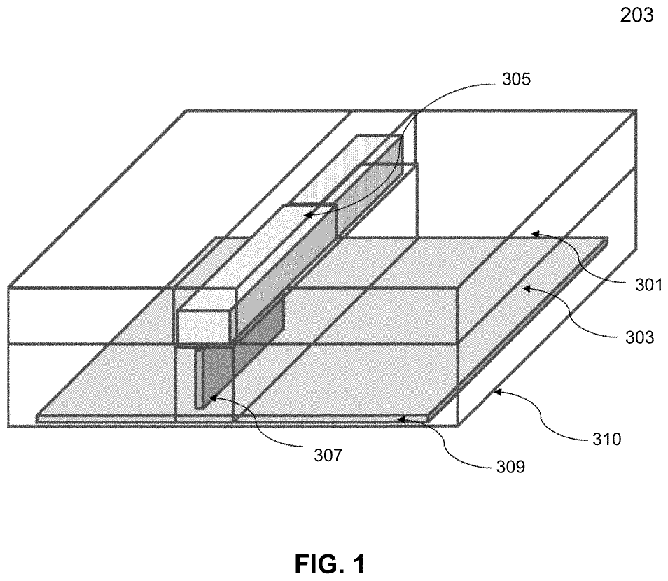

FIG. 1 is a perspective view of a server chassis 203 according to one embodiment. In one embodiment, server chassis 203 includes cooling unit 305 and a peripheral device 307 to be cooled by cooling unit 305. Server chassis 203 may include one or more IT components and/or a tray to contain one or more IT components (e.g., central processing units or CPUs, and/or peripheral devices). IT components may perform data processing tasks, where the IT components may include software installed in a storage device, loaded into the memory, and executed by one or more processors to perform the data processing tasks. Server chassis 203 may include a host server or a compute server (such as CPU server or GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to a compute server (having one or more GPUs) managed by the host server. The compute servers perform the actual tasks, which may generate heat during the operations.

In one embodiment server chassis 203 can be divisible into a top cooling section 301 and a bottom IT component section 303. The top section includes various cooling components to cool a server in the server chassis, such as cooling units 305. Bottom IT component section 303 can include, a tray 310, main electronic board 309 placed on tray 310, and one or more peripheral devices 307 connected to main electronic board 309. Peripheral device 307 can be a GPU, application specific integrated circuits (ASIC), computing accelerators, high computing based IC chips or chiplets, and so forth. The peripheral devices can interface with main electronic board 309 through a peripheral expansion bus, such as PCIe.

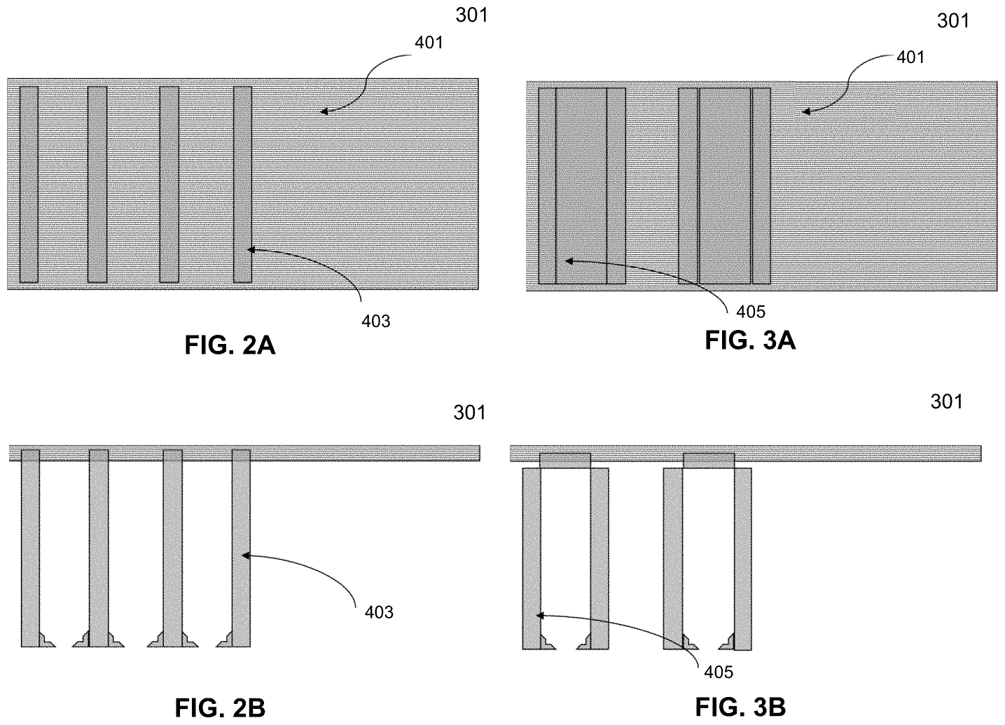

FIGS. 2A and 3A are top views of a top cooling section 301 of a server chassis 203 according to some embodiments. FIGS. 2B and 3B are front views of a top cooling section 301 illustrating a frame 403 having a single mounting arm and a frame 405 having double mounting arms according to some embodiments.

Referring to FIGS. 2-3, top cooling section 301 can include a secured panel 401. The secured panel 401 can be either integrated as one piece with server chassis 203 or can be a separate panel which can be flexibly assembled to server chassis 203. In one embodiment, secured panel 401 can be secured to a side panel of server chassis.

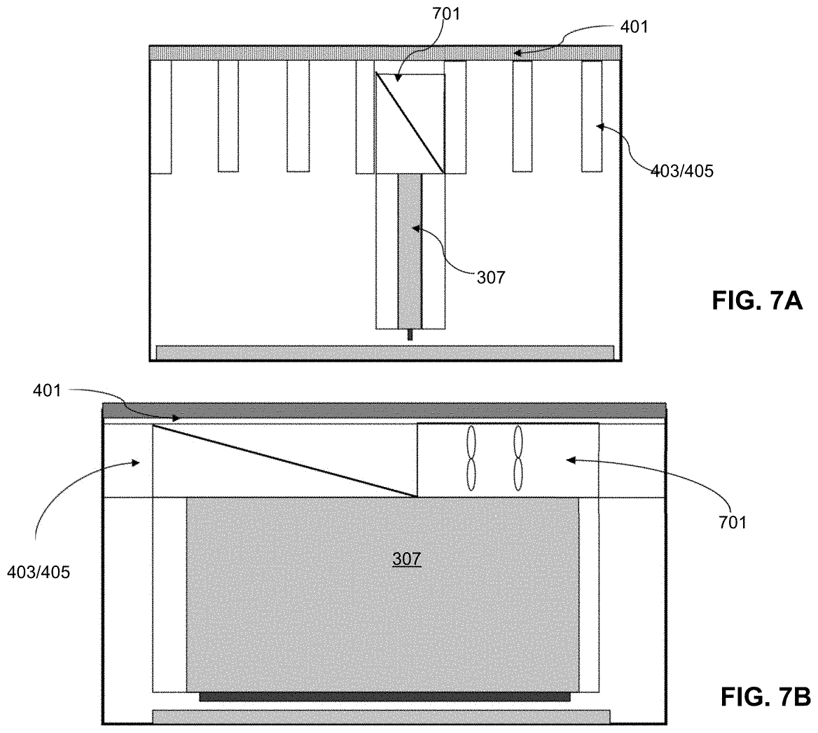

In one embodiment, secured panel 401 can be used to secure one or more frames 303-305 to server chassis 203. For example, secure panel 401 can include one or more recessed channels. Frames 403-405 can slide into a recessed channel and frames 403-405 are lockable to the recessed channel via a locking kit (as further shown in FIGS. 5A-5C). In one embodiment, frames 403-405 is either a single frame 403 or a double frame 405. Single frame 403 can include a single fixed mounting arm, and double frame 405 can include two fixed mounting arms. Frames 403-405, in turn, are used to attach to a cooling unit, as further shown in Figures 7-9. Note that the length of the arms of frames 403-405 can vary to support cooling units of different form factors.

As shown in FIGS. 2-3, the number of frames 403-405, as well as the locations of frames 403-405 can vary. The varying frame counts and/or locations enable the secured panel 401 to support server systems with different power densities and peripheral devices of different configurations.

In one embodiment, double frame 405 can be used to attach to a cooling unit having standard form factor cooling devices, since a spacing between the two arms of a double frame is fixed and cannot be changed. In one embodiment, single frame 403 can be used to attach a cooling unit with cooling devices of a non-standard form factor. In one embodiment, an arm of a single frame or a double frame can be used to secure cooling devices on one side of the arm or both sides of the arm. In some embodiments, the dimensions of the frame can vary.

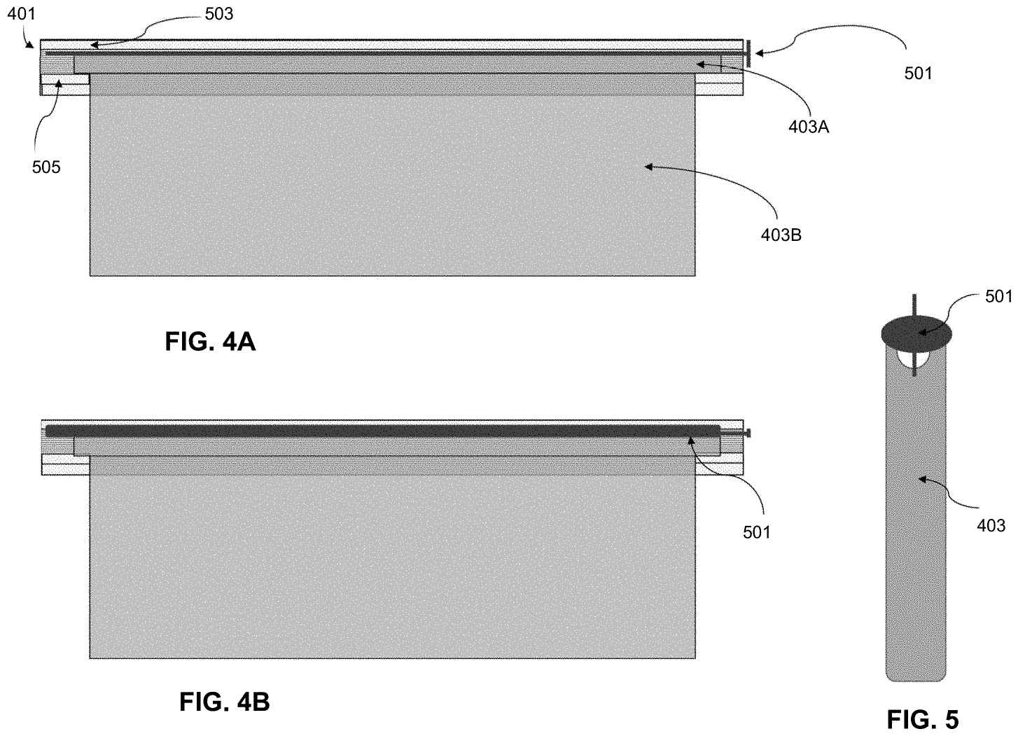

FIG. 4A is a side view of a top cooling section illustrating a locking kit in an unlocked position according to one embodiment. FIG. 4B is a side view of a top cooling section illustrating a locking kit in a locked position according to one embodiment.

As shown in FIG. 4A, secured panel 401 includes one or more top cushion layers 503 and one or more bottom cushion layers 505. In one embodiment, top and bottom cushion layers 503-505 include layers of flexible materials and/or mechanical cushions. In one embodiment, a flexible material/mechanical cushion of a top cushion layer 503 faces a flexible material/mechanical cushion of a bottom cushion layer 505. In one embodiment, secured panel 401 includes a structural beam that extends from a top cushion layer 503 to a bottom cushion layer 505 to provide structural support between top and bottom cushion layers 503-505.

In one embodiment, two cushion layers 503-505 form a recessed channel for a frame to be assembled to secured panel 401. A frame 403 can include two portions: a top portion 403A and a bottom portion 403B. Top portion 403A can be shaped to mechanically fit in the recessed channel formed by cushion layers 503-505 within secured panel 401. Bottom portion 403B can be used to integrate with one or more cooling units.

In one embodiment, a locking kit 501 is provided to structurally lock a frame 403 to a secure panel 401. When locking kit 501 is in an unlocked position, as shown in FIG. 4A, a position of a frame can be slidably adjusted along a recessed channel. In one embodiment, locking kit 501 can be turned to place locking kit 501 in a locked position. As shown in FIG. 4B, locking kit 501 in a locked position secures frame 403 against a top cushion layer 503 or a bottom cushion layer 505 of secured panel 401.

FIG. 5 is a front view of a frame illustrating an example locking kit according to one embodiment. As shown in FIG. 5, locking kit 501 can include a tube or plate with an elliptical-shaped body, where one end of frame 403-405 can include an elliptical opening for locking kit 501 to be inserted in between frame 403-405 and a top cushion layer. In one embodiment, locking kit 501 can resemble a rod with a flat plate body having an elliptical-shaped head. In one embodiment, when locking kit is inserted into frame 403, in between frame 403 and a top cushion layer of secured panel 401, locking kit 501 can be turned approximately 90 degrees to lock frame 403 onto secured panel 401. In one embodiment, when locking kit 501 is in a locked position, rod body of locking kit 501 is pressed against a top cushion layer 503 and frame 403. In one embodiment, when locking kit 501 is in a locked position, top portion of frame 403A is pressed against a bottom cushion layer 505 of secured panel 401.

In one embodiment, secure panel 401 and frames 403-405 are used as structural support for both cooling units and peripheral devices coupled to frames 403-405.

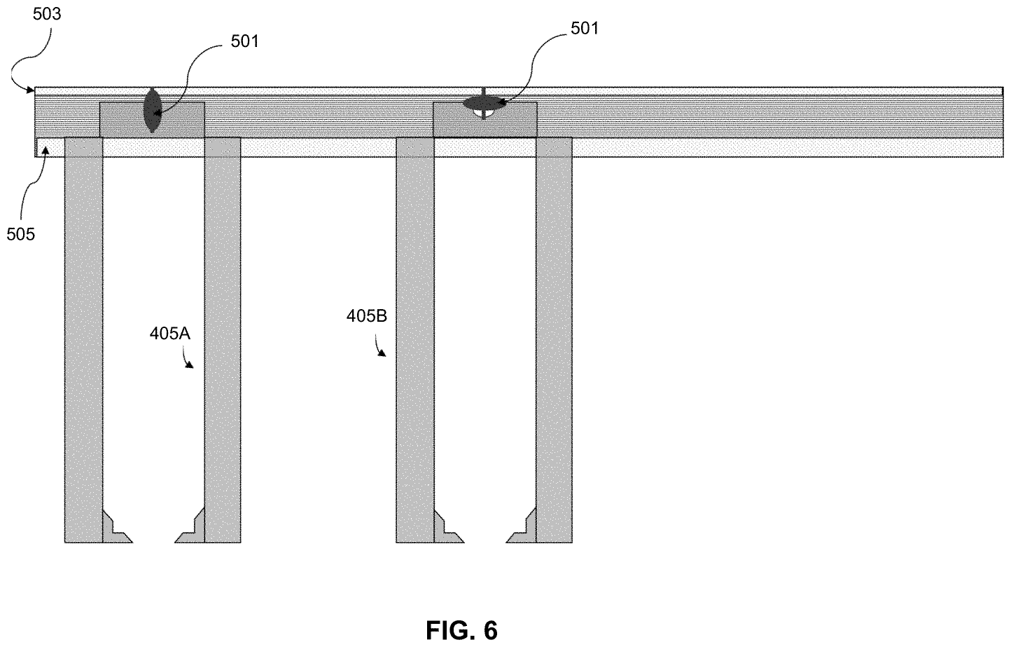

FIG. 6 is a front view of a top cooling section illustrating a locked and an unlocked locking kits according to one embodiment. FIG. 6 shows that a double frame 405 includes a top portion and two mounting arms. The top portion of frame 405 is assembled in a recessed channel, in between a top cushion layer 503 and a bottom cushion layer 505, which together supports the top portion of double frame 405. Frame 405A on the left shows locking kit 501 in a locked position and frame 405B on the right shows locking kit 501 in an unlocked position.

FIG. 7A is a front view of a chassis 203 assembled with one or more cooling units according to one embodiment. FIG. 7B is a side view of a chassis 203 assembled with one or more cooling units according to one embodiment.

As shown in FIGS. 7A-7B, a cooling unit 701 together with an electronic package 307 are assembled to chassis 203 using secured panel 401 and frames 403/405. It can be seen that frames 403/405 are used for securing a cooling unit 701. In one embodiment, cooling unit 701 can include a heat exchanger, a radiator and/or a fan, where cooling unit 701 is situated between any two arms of frames 403/405.

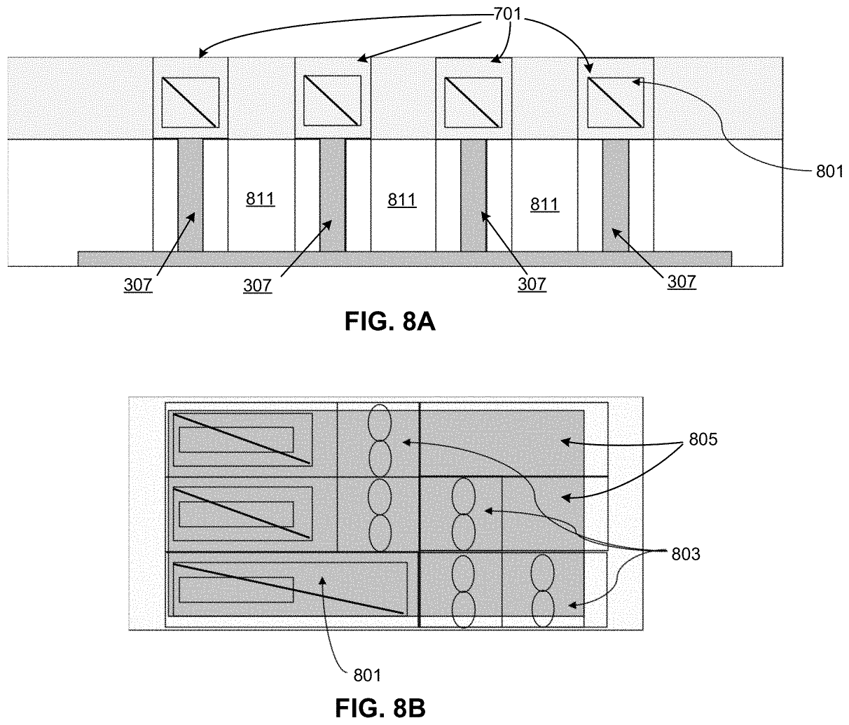

FIG. 8A is a front view of a chassis assembled with one or more cooling units according to one embodiment. FIG. 8B is a top view of the chassis of FIG. 8A.

FIGS. 8A-8B show four cooling units 701 are assembled in chassis 203. FIG. 8B shows secured panel 401 is covered by cooling units 701, where cooling units 701 are secured by one or more frames 403-405 (not shown). In one embodiment, cooling units 701 can include one or more cooling devices. The cooling device can be a fan, radiator, heat exchanger, a liquid cooled cold plate, etc.

In one embodiment, referring to FIG. 8B, spacings not covered by cooling components 801-803 can be covered by blank panels 805. The blank panels 805 together with cooling units 701 can form air channels 811 between peripheral devices to channel an airflow from a frontend to a backend of server chassis.

FIG. 8B shows channels that are formed between frames 403-405 can be equipped with different cooling components, such as fans 803, and heat exchangers 801. In one embodiment, length of arms of frames 403-405 (not shown) can be different, e.g., full length or half-length frames. For example, large cooling fans 803 can be assembled among one or more full length frames and then inserted into server chassis. Then, cooling heat exchangers 801 can be assembled between a full length frame and a half-length frame and inserted into server chassis. In one embodiment, a cooling fan 803 can be used as a shared fan for one or more heat exchangers 801.

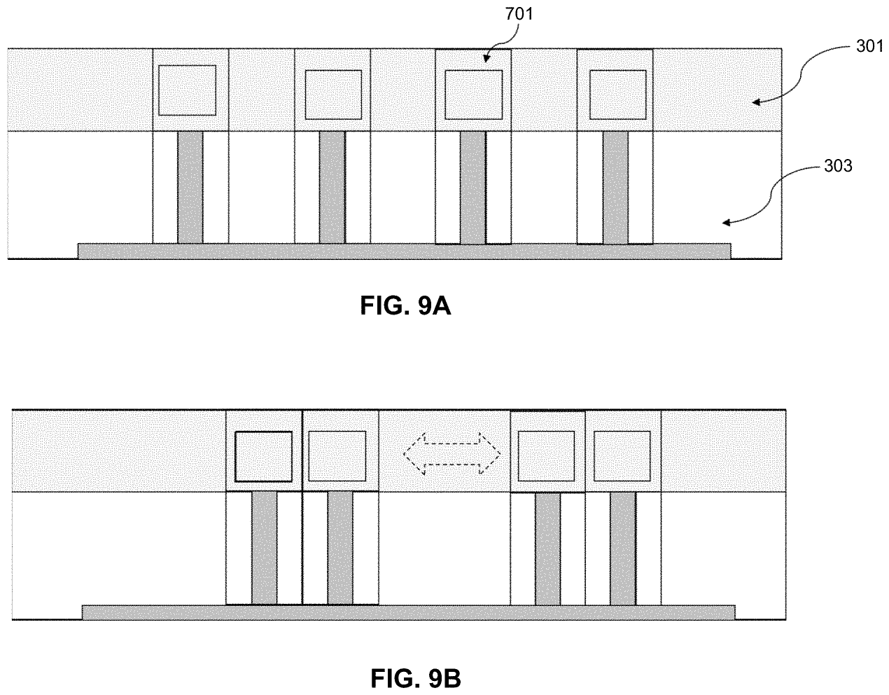

FIG. 9A is a front view of a chassis assembled with one or more cooling units support a first peripheral devices arrangement according to one embodiment. FIG. 9B is a front view of a chassis assembled with one or more cooling units support a second peripheral devices arrangement according to one embodiment.

As shown in FIGS. 9A-9B, because main server boards can vary in the number of peripheral expansions and their locations, thus, server IT component section 303 may be configured with a different number of peripheral devices at different locations. For example, IT components in section 303 can have various number of PCIe expansion slots and the PCIe expansion slots locations may vary. Here, top section 301 allows a different number of cooling units 701 to be installed and at various locations, thus, this flexibility of top section 301 improves interoperability among different server board designs.

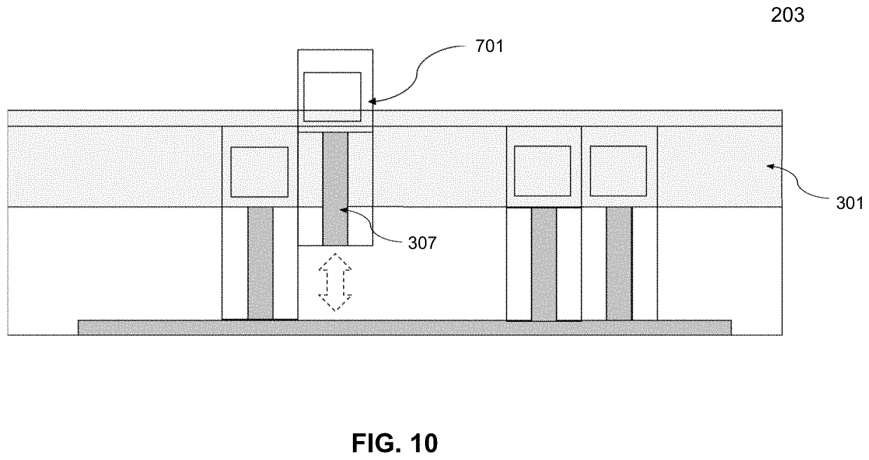

FIG. 10 illustrates that a cooling unit is insertable from the top of chassis 203 according to one embodiment. As shown, in one embodiment, the design of secured panel should allow a cooling unit to be installed to a server before installing the server to a rack. In one embodiment, part of top section 301 is not fully covered by secured panel 401 (not shown). For example, recessed channels formed by secured panel 401 (not shown) may not span a full length of chassis 203. In one embodiment, recessed channels can be formed at opposing sides of a secured panel while a mid-portion of secured panel has an opening for a cooling unit to be inserted into. In this case, when server chassis 203 is detached from an electronic rack, frame 403-405 and cooling unit 701, together with peripheral device 307 can be inserted into server 203 from the opening. A locking kit then secures frame 403-405 to secured panel 401.

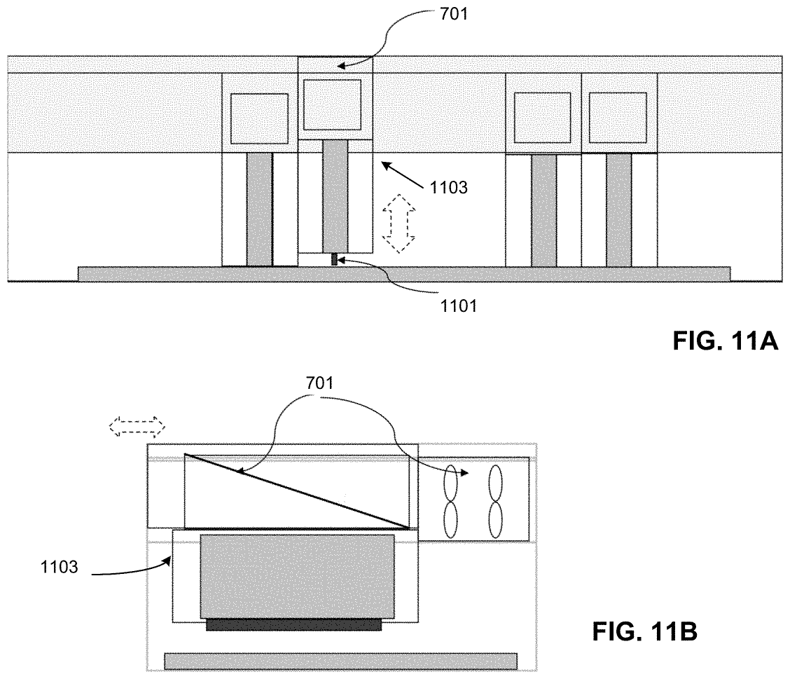

FIG. 11A is a front view, and FIG. 11B is a side view, of a chassis illustrating cooling units and peripheral devices are insertable and/or removable from a front/back of a chassis according to one embodiment. FIGS. 11A-11B show that server chassis 203 allows the addition and/or removal of cooling units and/or electronics packages even while the server chassis is populated in an electronic rack. In one embodiment, frames, when unlocked, can be moved along a recessed channel formed by two cushion layers. In one embodiment, an entire peripheral package 1103 (e.g., electronics package and cooling unit), when unlocked, can be lifted as shown in FIG. 11B. For example, when a cooling unit 701 is required to be serviced or removed from chassis 203, one or more locking kits (not shown) of frames can be turned and then the frames can be lifted to remove a peripheral package 1103 from a peripheral connector 1101. Peripheral package 1103 can then be moved along a recessed channel and removed horizontally, from either the front side or rear side of chassis 203.

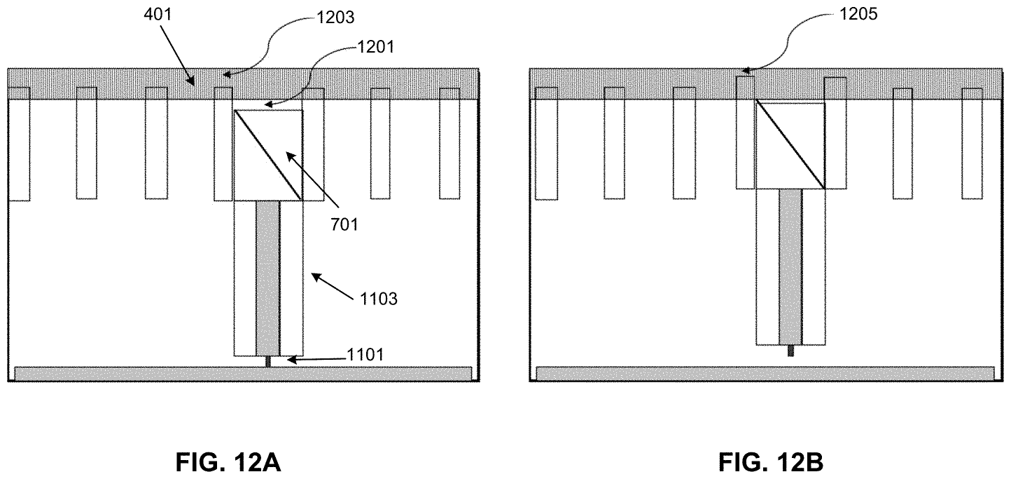

FIG. 12A is a front view of a chassis illustrating one or more spacings when a peripheral PCB is interfaced with a main board according to one embodiment. FIG. 12B is a front view of FIG. 12A. FIGS. 12A-12B show that chassis 204 with spacings 1201-1205 can be used for the addition and/or removal of a peripheral device 1103 from chassis 203 while chassis 203 remains in an electronic rack. For example, spacing 1201 ensures an adequate clearance between cooling unit 701 and secured panel 401 when peripheral device 1103 is unlocked and removed through a front or rear side of chassis. Spacings 1203 and 1205 can be a distance from a frame to a top cushion layer of secured panel 401 when frame is locked and when frame is unlocked, respectively. For example, as shown in FIG. 12A, when a frame is locked, there exists spacing 1203 between a frame and a top cushion layer of secured panel 401. As shown in FIG. 12B, when a frame is locked, there exists spacing 1205 between a frame and a top cushion layer of secured panel 401. In one embodiment, when a frame is locked, peripheral device is interfaced with a peripheral slot 1101. Spacings 1203-1205 can provide adequate clearance so peripheral package 1103 can interface to and/or de-interfaced from peripheral slot 1101 with a turn of a locking kit.

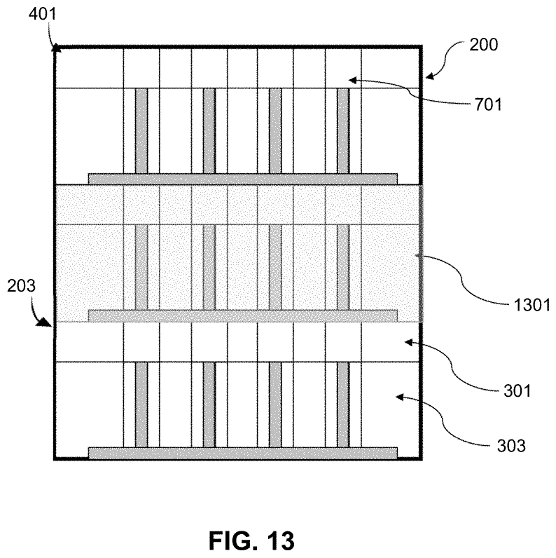

FIG. 13 is a front view of a rack according to one embodiment. FIG. 13 illustrates a rack with different server system implementations. For example, in one embodiment, a server system can include a chassis 203 having top and bottoms sections 301-302. In one embodiment, a cooling section, such as cooling section 301 of FIG. 1, can be implemented as part of a server system, as illustrated by server 1301. In this case, a secured panel (including a locking kit) of a cooling section can be structurally secured to a main board of server 1301 instead of a server chassis. In some embodiments, secured panel 401, which supports a same locking mechanism that is described in FIG. 5, can be implemented directly on rack 200, instead of being implemented as part of a server chassis. In this case, rack 200 can include one or more secured panels 401, where a cooling unit 701 can be directly attached to the one or more secured panels of rack 200.

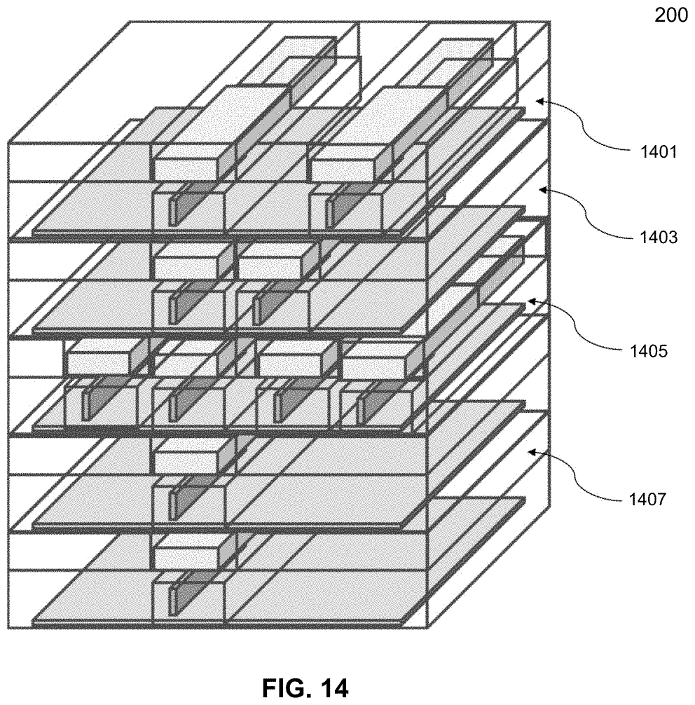

FIG. 14 is a perspective view of a server rack 200 with server systems of different power densities and peripheral configurations according to one embodiment. Electronic rack 200 can include a number of server slots (e.g., standard shelves or chassis configured with an identical or similar form factor), and a number of server chassis capable of being inserted into and removed from the server slots. Each server chassis can be associated with a host server or a compute server. Moreover, one or more cooling fans can be associated with the server chassis to provide air cooling to the host/compute servers contained therein. Cool airflows can enter electronic rack 200 through their frontend and warm/hot airflows can exit the electronic rack 200 from their backend.

As shown in FIG. 14, server systems 1401-1407 can be configured with different power densities and/or different peripheral device arrangements within a single rack, using server chassis 203. For example, server systems 1401-1407 can be server setups with different numbers of peripheral devices and/or peripheral configurations. System 1405 can be a high power density and high performance system with four peripheral devices. Server systems 1401-1403 can have a same power density but with different server board layouts. Thus, rack 200 can include server systems 1401-1407 configured differently using server chassis 203 to satisfy different computing requirements. Moreover, an airflow management and cooling system configuration can be individualized within each server system 1401-1407, independent of one another.

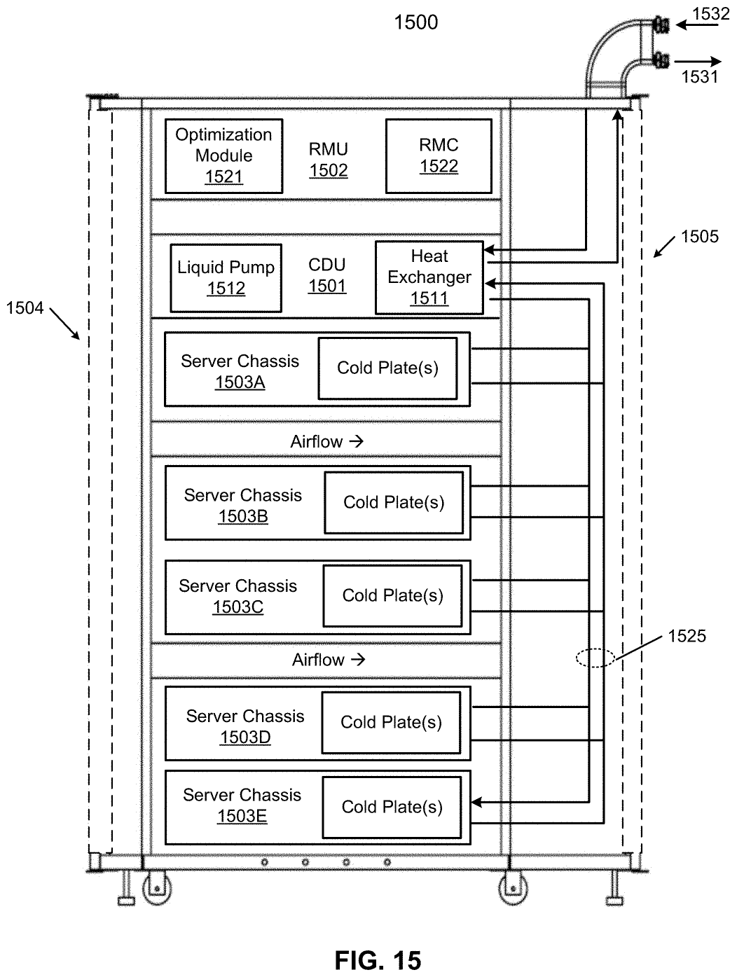

FIG. 15 is block diagram illustrating an electronic rack according to one embodiment. Electronic rack 1500 may represent any of the electronic racks as described throughout this application. According to one embodiment, electronic rack 1500 includes, but is not limited to, coolant distribution unit (CDU) 1501, rack management unit (RMU) 1502, and one or more server chassis 1503A-1503E (collectively referred to as server chassis 1503). Server chassis 1503 can be inserted into an array of server slots (e.g., standard shelves) respectively from frontend 1504 or backend 1505 of electronic rack 1500. Note that although there are five server chassis 1503A-1503E shown here, more or fewer server chassis may be maintained within electronic rack 1500. Also note that the particular positions of CDU 1501, RMU 1502, and/or server chassis 1503 are shown for the purpose of illustration only; other arrangements or configurations of CDU 1501, RMU 1502, and/or server chassis 1503 may also be implemented. In one embodiment, electronic rack 1500 can be either open to the environment or partially contained by a rack container, as long as the cooling fans can generate airflows from the frontend to the backend.

In addition, for at least some of the server chassis 1503, an optional fan module (not shown) is associated with the server chassis. Each of the fan modules includes one or more cooling fans. The fan modules may be mounted on the backends of server chassis 1503 or on the electronic rack to generate airflows flowing from frontend 1504, traveling through the air space of the sever chassis 1503, and existing at backend 1505 of electronic rack 1500.

In one embodiment, CDU 1501 mainly includes heat exchanger 1511, liquid pump 1512, and a pump controller (not shown), and some other components such as a liquid reservoir, a power supply, monitoring sensors and so on. Heat exchanger 1511 may be a liquid-to-liquid heat exchanger. Heat exchanger 1511 includes a first loop with inlet and outlet ports having a first pair of liquid connectors coupled to external liquid supply/return lines 1531-1532 to form a primary loop. The connectors coupled to the external liquid supply/return lines 1531-1532 may be disposed or mounted on backend 1505 of electronic rack 1500. The liquid supply/return lines 1531-1532, also referred to as room liquid supply/return lines, may be coupled to an external cooling system.

In addition, heat exchanger 1511 further includes a second loop with two ports having a second pair of liquid connectors coupled to liquid manifold 1525 (also referred to as a rack manifold) to form a secondary loop, which may include a supply manifold (also referred to as a rack liquid supply line or rack supply manifold) to supply cooling liquid to server chassis 1503 and a return manifold (also referred to as a rack liquid return line or rack return manifold) to return warmer liquid back to CDU 1501. Note that CDUs 1501 can be any kind of CDUs commercially available or customized ones. Thus, the details of CDUs 1501 will not be described herein.

Each of server chassis 1503 may include one or more IT components (e.g., central processing units or CPUs, general/graphic processing units (GPUs), memory, and/or storage devices). Each IT component may perform data processing tasks, where the IT component may include software installed in a storage device, loaded into the memory, and executed by one or more processors to perform the data processing tasks. Server chassis 1503 may include a host server (referred to as a host node) coupled to one or more compute servers (also referred to as computing nodes, such as CPU server and GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the computing nodes or compute servers (having one or more GPUs) managed by the host server. The compute servers perform the actual tasks, which may generate heat during the operations.

Electronic rack 1500 further includes optional RMU 1502 configured to provide and manage power supplied to servers 1503, and CDU 1501. RMU 1502 may be coupled to a power supply unit (not shown) to manage the power consumption of the power supply unit. The power supply unit may include the necessary circuitry (e.g., an alternating current (AC) to direct current (DC) or DC to DC power converter, battery, transformer, or regulator, etc.,) to provide power to the rest of the components of electronic rack 1500.

In one embodiment, RMU 1502 includes optimization module 1521 and rack management controller (RMC) 1522. RMC 1522 may include a monitor to monitor operating status of various components within electronic rack 1500, such as, for example, computing nodes 1503, CDU 1501, and the fan modules. Specifically, the monitor receives operating data from various sensors representing the operating environments of electronic rack 1500. For example, the monitor may receive operating data representing temperatures of the processors, cooling liquid, and airflows, which may be captured and collected via various temperature sensors. The monitor may also receive data representing the fan power and pump power generated by the fan modules and liquid pump 1512, which may be proportional to their respective speeds. These operating data are referred to as real-time operating data. Note that the monitor may be implemented as a separate module within RMU 1502.

Based on the operating data, optimization module 1521 performs an optimization using a predetermined optimization function or optimization model to derive a set of optimal fan speeds for the fan modules and an optimal pump speed for liquid pump 1512, such that the total power consumption of liquid pump 1512 and the fan modules reaches minimum, while the operating data associated with liquid pump 1512 and cooling fans of the fan modules are within their respective designed specifications. Once the optimal pump speed and optimal fan speeds have been determined, RMC 1522 configures liquid pump 1512 and cooling fans of the fan modules based on the optimal pump speeds and fan speeds.

As an example, based on the optimal pump speed, RMC 1522 communicates with a pump controller of CDU 1501 to control the speed of liquid pump 1512, which in turn controls a liquid flow rate of cooling liquid supplied to the liquid manifold 1525 to be distributed to at least some of server chassis 1503. Similarly, based on the optimal fan speeds, RMC 1522 communicates with each of the fan modules to control the speed of each cooling fan of the fan modules, which in turn control the airflow rates of the fan modules. Note that each of fan modules may be individually controlled with its specific optimal fan speed, and different fan modules and/or different cooling fans within the same fan module may have different optimal fan speeds.

Note that the rack configuration as shown is described for the purpose of illustration only; other configurations or arrangements may also be applicable. For example, CDU 1501 may be an optional unit. The cold plates of server chassis 1503 may be coupled to a rack manifold, which may be directly coupled to room manifolds 1531-1532 without using a CDU. Although not shown, a power supply unit may be disposed within electronic rack 1500. The power supply unit may be implemented as a standard chassis identical or similar to a sever chassis, where the power supply chassis can be inserted into any of the standard shelves, replacing any of server chassis 1503. In addition, the power supply chassis may further include a battery backup unit (BBU) to provide battery power to server chassis 1503 when the main power is unavailable. The BBU may include one or more battery packages and each battery package include one or more battery cells, as well as the necessary charging and discharging circuits for charging and discharging the battery cells.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A server chassis of an electronic rack, comprising:
a tray to contain one or more information technology (IT) components, wherein the server chassis is stackable in a stack on an electronic rack, wherein each server chassis is divisible into a top section and the bottom section and the bottom section includes the tray, wherein the top section comprises:
a secured panel, the secured panel being secured to the server chassis;
one or more frames adjustably attached to the secured panel; and
one or more cooling units attachable to the one or more frames, the one or more cooling units to interface with the one or more IT components to cool the one or more IT components, wherein the one or more frames are relocatable to a different position on the secured panel.

2. The server chassis of claim 1, wherein a frame includes a mountable arm and the one or more cooling units are mountable on the mounting arm.

3. The server chassis of claim 1, wherein the one or more IT components include one or more peripheral component interconnect express (PCIE) devices, and the one or more frames are relocatable to a different position on the secured panel while a server having the one or more IT components is in operation.

4. The server chassis of claim 1, wherein the secured panel includes one or more recessed channels, wherein a first portion of a frame is insertable into a recessed channel of the one or more recessed channels.

5. The server chassis of claim 1, further comprising a locking kit insertable between a first portion of a frame and the secured panel, the locking kit is turnable to lock the frame to the secured panel.

6. The server chassis of claim 1, wherein a locking kit includes an elliptical-shaped pin and a first end of a frame includes an elliptical-shaped opening, wherein the elliptical-shaped pin is insertable into the elliptical-shaped opening.

7. The server chassis of claim 1, wherein the secured panel includes one or more first cushion layers and one or more second cushion layers facing the one or more first cushion layers, wherein the one or more first cushion layers and the one or more second cushion layers form one or more recessed channels.

8. The server chassis of claim 1, wherein if a locking kit is in a locked position, the lock kit causes a top portion of a frame to press against a second cushion layer, which in turn, causes a PCIE device coupled to the frame to interface with a PCIE slot.

9. The server chassis of claim 1, wherein if a locking kit is in an unlocked position, a PCIE device associated with the locking kit is elevated from a PCIE slot.

10. The server chassis of claim 1, wherein the cooling unit includes a radiator or a cooling fan, wherein the cooling unit can be integrated to the top section, individually, or as a peripheral package, wherein the peripheral package includes the cooling unit and a peripheral device.

11. An electronic rack of a data center, comprising:
a plurality of server chassis arranged in a stack, each server chassis is divisible into a top section and a bottom section, wherein the bottom section comprises a tray to contain one or more information technology (IT) components, wherein the top section comprises:
a secured panel, the secured panel being secured to the server chassis;
one or more frames adjustably attached to the secured panel; and
one or more cooling units attachable to the one or more frames, the one or more cooling units to interface with the one or more IT components to cool the one or more IT components, wherein the one or more frames are relocatable to a different position on the secured panel.

12. The electronic rack of claim 11, wherein a frame includes a mountable arm and the one or more cooling units are mountable on the mounting arm.

13. The electronic rack of claim 11, wherein the one or more IT components include one or more peripheral component interconnect express (PCIE) devices, and the one or more frames are relocatable to a different position on the secured panel while a server having the one or more IT components is in operation.

14. The electronic rack of claim 11, wherein the secured panel includes one or more recessed channels, wherein a first portion of a frame is insertable into a recessed channel of the one or more recessed channels.

15. The electronic rack of claim 11, further comprising a locking kit insertable between a first portion of a frame and the secured panel, the locking kit is turnable to lock the frame to the secured panel.

16. An electronic rack of a data center, comprising:
a secured panel, the secured panel being secured to the electronic rack;
one or more frames adjustably attached to the secured panel; and
one or more cooling units attachable to the one or more frames, the one or more cooling units to interface with the one or more IT components to cool the one or more IT components, wherein the one or more frames are relocatable to a different position on the secured panel.

17. The electronic rack of claim 16, wherein each frame includes a mountable arm and the one or more cooling units are mountable on the mounting arm.

18. The electronic rack of claim 16, wherein the one or more IT components include one or more peripheral component interconnect express (PCIE) devices, and the one or more frames are relocatable to a different position on the secured panel while a server having the one or more IT components is in operation.

19. The electronic rack of claim 16, wherein the secured panel includes one or more recessed channels, wherein a first portion of a frame is insertable into a recessed channel of the one or more recessed channels.

20. The electronic rack of claim 16, further comprising a locking kit insertable between a first portion of a frame and the secured panel, the locking kit is turnable to lock the frame to the secured panel.
